(19) United States
(12) Patent Application Publication
(10) Pub. No.: US 2008/0080295 A1
(43) Pub. Date: Apr. 3, 2008

(54) EMBEDDED SEMICONDUCTOR MEMORY DEVICE HAVING SELF-TIMING CONTROL SENSE AMPLIFIER

(76) Inventors: Toshimasa Namekawa, Tokyo (JP); Hiroshi Ito, Yokohama-shi (JP); Osamu Wada, Yokohama-shi (JP); Atsushi Nakayama, Yokohama-shi (JP); Hiroaki Nakano, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/833,054

(22) Filed: Aug. 2, 2007

(30) Foreign Application Priority Data
Sep. 29, 2006 (JP) 2006-268807

(51) Int. Cl. G11C 8/00

(52) U.S. Cl. 365/230.06

(57) ABSTRACT

A semiconductor memory device includes a precharge unit to precharge a reference bit line and a selection bit line with the same potential, the selection bit line being connected to a target nonvolatile storage element from which data is to be read, a charge extraction unit to extract charges from the reference bit line and the selection bit line with the same current characteristic, a recharge unit which recharges the reference bit line with a current that is smaller than the charges extracted by the charge extraction unit, and a plurality of differential amplifiers which compare a potential of the reference bit line and a potential of the selection bit line with a reference potential. The semiconductor memory device further includes an output circuit which outputs data from the target nonvolatile storage element connected to the selection bit line, based on outputs of the differential amplifiers.

### CROSS-REFERENCE TO RELATED APPLICATIONS

This application is based upon and claims the benefit of priority from prior Japanese Patent Application No. 2006-268807, filed Sep. 29, 2006, the entire contents of which are incorporated herein by reference.

### BACKGROUND OF THE INVENTION

1. Field of the Invention

The present invention relates to a semiconductor memory device. More specifically, the invention relates to an embedded nonvolatile memory having a self-timing control sense amplifier.

2. Description of the Related Art

An embedded nonvolatile memory has recently been required for the use of storing redundancy information of a static random access memory (SRAM) or a dynamic random access memory (DRAM). The embedded nonvolatile memory can be mounted on a semiconductor integrated circuit chip. It is expected that the memory will be used to store control information for controlling the characteristic of an analog circuit, to hold an encryption key for encrypting information, to manage identification information for identifying a chip, and the like.

At present, a nonvolatile memory to which data can be written only once, which is called a one time programmable (OTP) memory, is known as one for the uses described above. Some OTP memories use as a storage element a current fuse element (e-Fuse element) that stores data by varying the components of wiring materials and irreversibly varying the electrical resistance, other OTP memories use as a storage element an antifuse element that stores data by destroying the gate insulation film of a normal metal oxide semiconductor (MOS) transistor element and irreversibly varying the insulation resistance (see, for example, H. Ito et al., “Pure CMOS One-time, Programmable Memory using Gate-Ox Anti-fuse,” Proceedings of the IEEE 2004, Custom Integrated Circuits Conference, pp. 469-472).

For the uses described above, a nonvolatile memory to which data can be written many times, which is called a many times programmable (MTP) memory, can be used. The MTP memory includes an erasable programmable read only memory (EPROM) and a ferroelectric random access memory (FeRAM). The EPROM uses a normal MOS transistor element as a storage element and stores data by bringing the gate wiring of the transistor element into a floating state (floating gate) and varying the threshold voltage of the transistor element in accordance with the injection of hot electrons or that of charges by a tunnel phenomenon. The FeRAM uses a capacitor storage element having a ferroelectric as an insulation film and stores data by spontaneously polarizing the ferroelectric by the application of a voltage to vary the capacity of a capacitor.

Most of the nonvolatile memories described above store data by varying the properties of materials constituting a storage element. However, the storage element of such a nonvolatile memory has the drawback that an electrical signal generated in read mode is very small because the variations of electrical characteristics due to the presence or absence of stored data, such as the variations of current, resistance, capacity and voltage, is small.

An antifuse element is configured to store data by destroying the gate insulation film of a MOS transistor element, and a difference in output current (electrical signal) between the presence and absence of the destruction is about 1 μA at worst. In contrast, an SRAM is configured to store data depending on the potential state of a flip-flop circuit, and a difference in output current between the presence and absence of hold data is as large as about 50 μA.

In an embedded nonvolatile memory that is required to be mounted on the same chip together with a high density memory, an analog circuit and a high-speed logic circuit, a step exclusively for forming a storage element in order to lower manufacturing costs is often omitted. In this case, the electrical characteristics of the storage element, such as a time period for programming data and an amount of current for reading data, is greatly deteriorated. Comparing a versatile nonvolatile memory and an embedded nonvolatile memory in an EPROM that holds data by storing charges in a floating gate, there is a clear difference in variation of electrical characteristics between them. Particularly in a versatile nonvolatile memory called a NAND flash, by optimizing an element structure and a manufacturing process such as forming a floating gate and a control gate to have a stacked structure, the amount of variation in the threshold voltage of a transistor due to the presence or absence of charges stored in the floating gate reaches 1V. In contrast, according to an embedded nonvolatile memory such as an MTP memory, the above optimization is not performed; accordingly, parasitic capacitance is increased. Hence, the amount of variation in the threshold voltage of a transistor becomes not larger than half (0.5V) of that in the versatile nonvolatile memory described above.

As has been described, in the embedded nonvolatile memory, an electrical signal generated from a storage element is very small. A technique of amplifying a small output current with high precision to read data out of the storage element is therefore essential to the embedded nonvolatile memory. As this technique, a high-precision analog amplifier can be used. In this case, too, however, the embedded nonvolatile memory is subjected to its unique constraints.

Since a high-precision analog amplifier is generally of large circuit size, its possession area is increased. If a specific element is required for an analog circuit, manufacturing steps become complicated and manufacturing costs become high. The analog amplifier having these problems cannot be applied to an embedded nonvolatile memory.

In order to amplify a small output current with high precision, usually, characteristic variations of elements that compose an amplifier need to be suppressed. To meet this need, it is effective to increase the size of the elements; however, the increase in size increases the internal impedance of the amplifier. The higher the precision of the amplifier, the lower the operation speed thereof. It can thus be thought that the amplifier is increased in speed by causing a large current to flow through the amplifier; however, a high density memory device is increased in noise. To resolve the problem of noise is difficult for an embedded nonvolatile memory.

In conclusion, an embedded nonvolatile memory that generates only a small output current has the problem that its read speed is very low.

### BRIEF SUMMARY OF THE INVENTION

According to a first aspect of the present invention, there is provided a semiconductor memory device comprising:

a plurality of row selection lines arranged in a row direction;

a plurality of bit lines arranged in a column direction;

a plurality of nonvolatile storage elements arranged at nodes between the row selection lines and the bit lines, the nonvolatile storage elements storing data by irreversibly varying electrical characteristics;

at least one reference bit line arranged in the column direction;

a precharge unit to precharge the reference bit line and a selection bit line of the bit lines with a same potential, the selection bit line being connected to a target nonvolatile storage element from which data is to be read;

a charge extraction unit to extract charges from the reference bit line and the selection bit line with a same current characteristic;

a recharge unit which is connected to the reference bit line to recharge the reference bit line with a current that is smaller than the charges extracted by the charge extraction unit;

a plurality of differential amplifiers which compare a potential of the reference bit line and a potential of the selection bit line with a reference potential; and

an output circuit which outputs data from the target nonvolatile storage element connected to the selection bit line, based on outputs of the differential amplifiers.

According to a second aspect of the present invention, there is provided a semiconductor memory device comprising:

a plurality of row selection lines arranged in a row direction;

a plurality of nonvolatile storage elements connected to the row selection lines via selection switches, the nonvolatile storage elements storing data by irreversibly varying electrical characteristics;

a plurality of bit lines arranged in a column direction, the bit lines being a pair of bit lines including a true bit line and a complementary bit line, a given number of nonvolatile storage elements arranged in the column direction being connected to one of the true and complementary bit lines via selection switches selected by odd-numbered row selection lines of the row selection lines, a given number of nonvolatile storage elements arranged in the column direction being connected to the other of the true and complementary bit lines via selection switches selected by even-numbered row selection lines of the row selection lines, and the one of the true and complementary bit lines being set as a selection bit line and the other of the true and complementary bit lines being set as a reference bit line in accordance with a target storage element from which data is to be read;

a precharge unit to precharge the reference bit line and the selection bit line with a same potential;

a charge extraction unit to extract charges from the reference bit line and the selection bit line with a same current characteristic;

a recharge unit which recharges the reference bit line with a current that is smaller than the charges extracted by the charge extraction unit;

a plurality of differential amplifiers which compare a potential of the reference bit line and a potential of the selection bit line with a reference potential; and

an output circuit which outputs data from the target nonvolatile storage element connected to the selection bit line, based on outputs of the differential amplifiers.

According to a third aspect of the present invention, there is provided a semiconductor memory device comprising:

a plurality of row selection lines arranged in a row direction;

a plurality of nonvolatile storage elements connected to the row selection lines via selection switches, the nonvolatile storage elements storing data by irreversibly varying electrical characteristics;

a plurality of bit lines arranged in a column direction, the bit lines being a pair of bit lines including a true bit line and a complementary bit line, a given number of nonvolatile storage elements arranged in the column direction being connected to one of the true and complementary bit lines via selection switches selected by odd-numbered row selection lines of the row selection lines, a given number of nonvolatile storage elements arranged in the column direction being connected to the other of the true and complementary bit lines via selection switches selected by even-numbered row selection lines of the row selection lines, and the one of the true and complementary bit lines being set as a reference bit line and the other of the true and complementary bit lines being set as a selection bit line in accordance with a target storage element from which data is to be read;

a precharge unit to precharge the reference bit line and the selection bit line with a same potential;

a charge extraction unit to extract charges from the reference bit line and the selection bit line with a same current characteristic;

a recharge unit which recharges the reference bit line with a current that is smaller than the charges extracted by the charge extraction unit;

a plurality of differential amplifiers which compare a potential of the reference bit line and a potential of the selection bit line with a reference potential; and

an output circuit which outputs data from the target nonvolatile storage element connected to the selection bit line, based on outputs of the differential amplifiers.

### BRIEF DESCRIPTION OF THE SEVERAL VIEWS OF THE DRAWING

FIG. 1 is a circuit diagram showing a configuration of an embedded nonvolatile memory according to a first embodiment of the present invention;

FIG. 2 is a timing chart illustrating a read operation of the embedded nonvolatile memory shown in FIG. 1;

FIG. 3 is a circuit diagram showing a configuration of an embedded nonvolatile memory according to a second embodiment of the present invention;

FIG. 4 is a timing chart illustrating a read operation of the embedded nonvolatile memory shown in FIG. 3;

FIG. 5 is a circuit diagram showing another configuration of the embedded nonvolatile memory shown in FIG. 1; and

FIG. 6 is a circuit diagram showing another configuration of the embedded nonvolatile memory shown in FIG. 3.

### DETAILED DESCRIPTION OF THE INVENTION

Embodiments of the present invention will be described with reference to the accompanying drawings. It should be noted that the drawings are schematic ones and the dimension ratios shown therein are different from the actual ones. The dimensions vary from drawing to drawing and so do the ratios of the dimensions. The following embodiments are directed to a device and a method for embodying the technical concept of the present invention and the technical concept does not specify the material, shape, structure or configuration of components of the present invention. Various changes and modifications can be made to the technical concept without departing from the scope of the claimed invention.

### FIRST EMBODIMENT

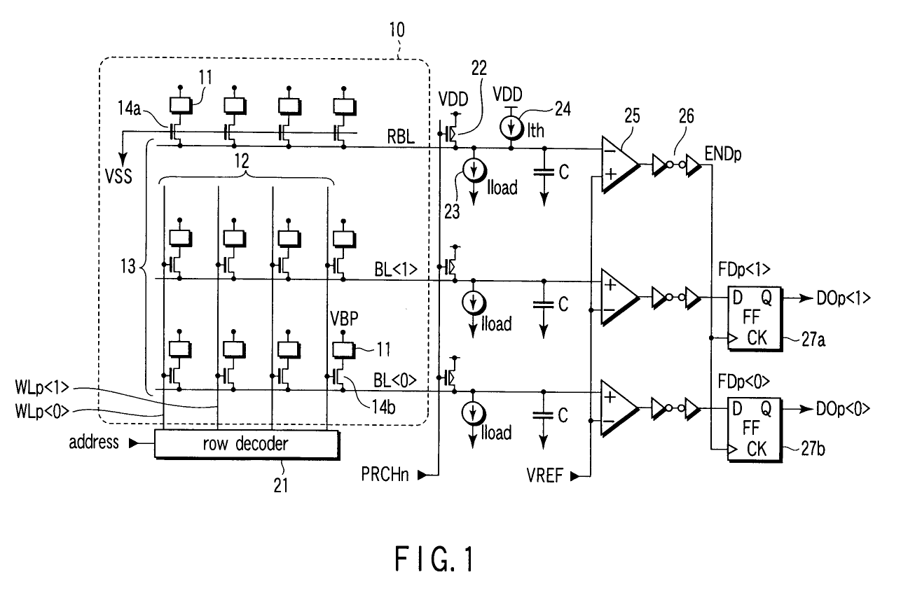

FIG. 1 shows a basic configuration of a semiconductor memory device according to a first embodiment of the present invention. The first embodiment will be described taking an embedded nonvolatile memory having a self-timing control sense amplifier as an example.

As shown in FIG. 1, the embedded nonvolatile memory uses as a nonvolatile storage element an antifuse element 11 that holds data by irreversibly electrical characteristics such as variations of resistance, capacity, voltage and current. The embedded nonvolatile memory is mounted on the same chip together with a high density memory, an analog circuit and a high-speed logic circuit in order to compose a memory device.

The embedded nonvolatile memory includes a memory cell array 10 in which a plurality of antifuse elements 11 (twelve antifuse elements in this embodiment) are arranged in matrix (four rows×three columns). The antifuse elements 11 are each formed of a normal MOS transistor element. A plurality of row selection lines (WL) 12 (four row selection lines are shown in FIG. 1) are arranged in the row direction of the memory cell array 10. A plurality of bit lines 13 (three bit lines are shown in FIG. 1) are arranged in the column direction of the memory cell array 10. Of the three bit lines 13, two bit lines are normal bit lines BL<0> and BL<1>, and the other bit line is a reference bit line RBL.

A given number of antifuse elements 11 (four antifuse elements are shown in FIG. 1) in a column are connected to the reference bit line RBL via respective selection switches 14a each formed of an N-type MOS transistor. One terminal (e.g., gate electrode) of an antifuse element 11 is connected to its corresponding selection switch 14a. The other terminals (e.g., source, drain and well or substrate) of the antifuse element 11 are connected to a high-voltage source. A high voltage VBP at which the gate insulation film of the antifuse element 11 can be broken is applied in programming (selection) mode.

The gate electrodes of the selection switches 14a are connected to a common ground potential VSS such that the selection switches are not brought into conduction. In other words, the antifuse elements 11 connected to the reference bit line RBL are not used as storage elements for storing data (what is called dummy antifuse elements) in the first embodiment of the present invention.

A given number of antifuse elements 11 (four antifuse elements in this embodiment) in each column are connected to each of the normal bit lines BL<0> and BL<1> via their respective selections switches 14b formed of N-type MOS transistors. One terminal (e.g., gate electrode) of each antifuse element 11 is connected to its corresponding selection switch 14b. The other terminals (e.g., source/drain and well or substrate) of the antifuse element 11 is connected to a high-voltage source. A high voltage VBP at which the gate insulation film of the antifuse element 11 can be broken is applied in programming (selection) mode.

The gate electrode of each of the selection switches 14b is connected to its corresponding row selection line 12. The row selection line 12 is activated by a row decoder 21 selectively in response to an address signal supplied from outside the memory.

A precharge unit 22 and a charge extraction unit 23 are connected to each of the reference bit line RBL and normal bit lines BL<0> and BL<1>. The precharge unit 22 precharges each of the bit lines RBL, BL<0> and BL<1> with a voltage (e.g., power supply voltage VDD). The charge extraction unit 23 extracts charges from each of the bit lines RBL, BL<0> and BL<1> in accordance with the same current characteristic (Iload). The precharge unit 22 is configured by, e.g., a P-type MOS transistor connected between the power supply voltage VDD and each of the bit lines, and activated by a precharge signal (PRCHn) supplied to each of the gate electrodes from outside the memory.

A recharge unit 24 is also connected to the reference bit line RBL to recharge the reference bit line RBL with current (Ith) whose amount is smaller than that of current (I) extracted by the charge extraction unit 23. As will be described in detail later, the amount of current (Ith) supplied from the recharge unit 24 is a threshold value for determining whether data is stored in the antifuse elements 11.

A differential amplifier 25 is connected to each of the reference bit line RBL and normal bit lines BL<0> and BL<1> to compare a bit line potential with a reference potential (VREF) applied from outside the memory. The signal output from the differential amplifier 25 is amplified further by an amplifier 26 and converted into a digital signal.

Flip-flops 27a and 27b are connected to the output terminals of the amplifiers 26. The digital signal (end signal) ENDp output from the amplifier 26 is supplied to each clock terminal (CK) of the flip-flops 27a and 27b in accordance with the bit line potential applied from the reference bit line RBL. On the other hand, the digital signals (output signals) FDp<0> FDp<1> output from the amplifiers 26 are supplied to the data input terminals (D) of the flip-flops 27a and 27b. The outputs of the flip-flops 27a and 27b correspond to the read signals (output current or electrical signal) DOp<0> and DOp<1> of the nonvolatile memory.

A procedure for reading data from the antifuse elements 11 in the nonvolatile memory described above (read operation) will be described.

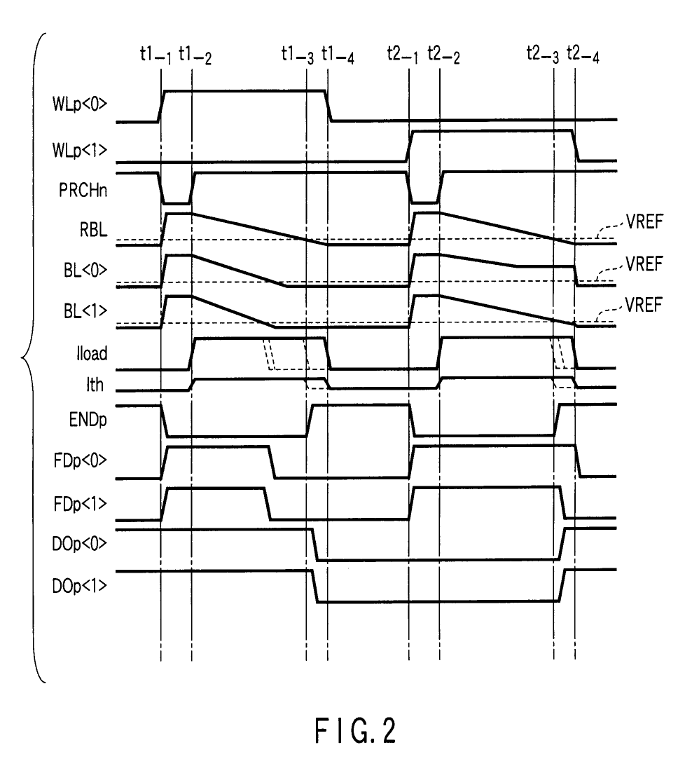

FIG. 2 is a timing chart, and its horizontal axis indicates a lapse of time. The timing chart shows variations (behavior) of potential and current of signals. The timing chart also shows two read operations, and the principle timings (t1-₁, t1-₂, t1-₃, t1-₄, t2-₁, t2-₂, t2-₃, t2-₄) are given by a one-dot-one-dash line. In FIG. 1, t1-₁, t1-₂, t1-₃ and t1-₄ represent first read operations and t2-₁, t2-₂, t2-₃, t2-₄ represent second read operations. The timing chart is prepared for illustrating a flow of the read operation in the first embodiment, and the values of time, potential, current or the like are not correct. For easy understanding, the number of row selection lines 12 is set to two (e.g., WLp<0>, WLp<1>).

First, data is read out of an antifuse element 11 as a first read operation. Assume here that one of the two row selection lines 12 (e.g., WLp<0>) is selected in response to an address signal supplied to a row decoder 21 (the other row selection line 12, e.g., WLp<1> is not selected). At the same timing t1-₁, a precharge signal PRCHn is supplied at the same timing t1-₁. The precharge signal PRCHn is a signal of negative logic and its low-potential state is an active one. Then, the precharge unit 22 using the precharge signal PRCHn as a gate signal is brought into conduction, and the potentials of the reference bit line RBL and normal bit lines BL<0> BL<1> become high.

At timing t1-₂, the precharge signal PRCHn is returned to an inactive state with the row selection line (WLp<0>) 12 kept in the selected state. At the same timing, the charge extraction unit 23 and recharge unit 24 are activated. Accordingly, the current characteristic Iload and current amount Ith increase. Thus, charges are extracted from a capacitor C added to each of the reference bit line RBL and normal bit lines BL<0> and BL<1>, and the potential of each of the bit lines lowers gradually.

When no data is written to a selected antifuse element 11, or when an antifuse element 11 is in a nonconducting state where it hardly causes cell current (Icell) to flow therethrough, the potentials of normal bit lines BL<0> and BL<1> vary more sharply than that of reference bit line RBL. The reason for this is as follows. The charge extraction unit 23 extracts charges from the normal bit lines BL<0> and BL<1> (for reading data) in accordance with the current characteristic Iload. In contrast, the unit 23 extracts charges from the reference bit line RBL in accordance with the current characteristic Iload and at the same time the recharge unit 24 recharges the reference bit line RBL in accordance with the current amount Ith. If, therefore, the cell current Icell that flows through an antifuse element 11 for reading data does not exceed the current amount Ith of the recharge unit 24, the potential of each of the normal bit lines BL<0> and BL<I> decreases more quickly than that of the reference bit line RBL.

However, the current amount Ith of the recharge unit 24 has to be smaller than the current characteristic Iload of the charge extraction unit 23. The speed at which the potential of each of the normal bit lines BL<0> and BL<1> decreases depends upon the current characteristic Iload of the unit 23, the current amount Ith of the unit 24 and the capacitance C of each of the normal bit lines BL<0> and BL<1>. The parasitic capacitance of each of the normal bit lines BL<0> and BL<1> can be used as the capacitance C, or a capacitive element having an adequate capacitance can be added in order to control the speed at which the potential of each of the normal bit lines BL<0> BL<1> lowers.

Then, the potential of the reference bit line RBL becomes equal to the reference potential VREF indicated by the broken line at timing t1-₃. This state is detected by the differential amplifier 25 that compares the potential of the reference bit line RBL and the reference potential VREF. The output of the differential amplifier 25 is amplified by the amplifier 26 into an end signal ENDp. The end signal ENDp is supplied to the clock terminal CK of each of the flip-flops 27a and 27b. At the leading edge of the end signal ENDp, the flip-flops 27a and 27b latch output signals FDp<1> and FDp<0> of the amplifiers 26 for amplifying the output signals of the differential amplifiers 25 connected to the normal bit lines BL<1> and BL<0>.

Finally, at timing t1-₄, the row selection line (WLp<0>) 12 is returned to an inactive state, and the charge extraction unit 23 and recharge unit 24 are each returned to an inactive state.

The above operation is a read operation for reading data from the antifuse element 11 in the first row from t1-₁ to t1-₄ (first read operation).

Then, a read operation for reading data from an antifuse element 11 in a second row is performed from t2-₁ to t2-₄. Since this read operation is almost the same as the above preceding read operation for reading data from the element 11 in the first row, only different operations will be described.

Of the row selection lines 12, a row selection line (WLp<1>) 12 in the second row is selected first at timing t2-₁. Then, at timing t2-₂, the precharge unit 22 is inactivated, while the charge extraction unit 23 and recharge unit 24 are activated, as in the preceding read operation.

Assume here that the antifuse element 11 selected in the current read operation stores data and is brought into conduction as an electrical characteristic. In most cases, however, the electrical characteristic of each of the antifuse elements 11 varies slightly, but the electrical characteristics widely vary from antifuse element to antifuse element. The influence of the variation appears as variations in potentials of bit lines BL<0> and BL<1>. The antifuse element 11 connected to the bit line BL<0> has relatively good electrical characteristics and allows a large amount of cell current Icell to flow therethrough. The potential of the bit line BL<0> is therefore much higher than the reference potential VREF indicated by the broken line.

In contrast, the antifuse element 11 connected to the bit line BL<1> does not have so good electrical characteristics. In this case, as shown in FIG. 2, the cell current Icell that flows through the antifuse element 11 is very feeble and smaller than the current characteristic Iload of the charge extraction unit 23. At the timing elapsed slightly from t2-₃, the potential of the bit line BL<1> is lower than the reference potential VREF. Even though only the feeble cell current Icell is obtained, if the cell current Icell is larger than the current amount Ith of cell current Icell supplied by the recharge unit 24, the speed at which the potential of bit line BL<1> decreases is lower than that at which the potential of reference bit line RBL decreases. Assume that the potential of bit line BL<1> to which the antifuse element 11 through which a feeble cell current Icell flows is connected is higher than the reference potential VREF the instant that an end signal ENDp indicating that the potential of reference bit line RBL becomes equal to the reference potential VREF indicated by the broken line is generated. The output signal FDp<1> indicating this becomes high. In short, the flip-flops 27a and 27 latch the output signals FDp<0> and FDp<1> generate read signals DOp<0> and DOp<1>, respectively, using the leading edge of the end signal ENDp as a clock signal.

Finally, at timing t2-₄, the row selection line (WLp<1>) 12 is returned to an inactive state, and so are the charge extraction unit 23 and recharge unit 24.

The above operation is a read operation for reading hold data from the antifuse element 11 in the second row from t2-₁ to t2-₄ (second read operation).

The configuration of the first embodiment allows hold data to be read out with high precision and quickly even though the variation in electrical characteristic due to the presence or absence of hold data in an antifuse element is very small.

As described above, in the nonvolatile memory using as a storage element an antifuse element for holding data by the variations of current, resistance, capacity, or voltage or current, a reference bit line to which a dummy antifuse element is connected is prepared. The reference bit line and a normal bit line to which an antifuse element from which data is to be read is connected, are each precharged with high potential. Then, the normal bit line starts to be discharged in accordance with a certain current amount and at the same time the reference bit line starts to be discharged in accordance with a current amount that is slightly smaller than that of the normal bit line. The potential of each of the bit lines is compared with a reference potential to detect which of the bit lines has a potential that becomes lower first than the reference potential, and data is read out of the antifuse element. In the embedded nonvolatile memory, even though the electrical signals from the antifuse element due to the changes of characteristics are very small, data can be read out of the antifuse element at high speed without using any high-precision analog amplifier or causing a large amount of current to flow through the antifuse element. Thus, a high-precision embedded nonvolatile memory having a self-timing control sense amplifier can easily be achieved.

### SECOND EMBODIMENT

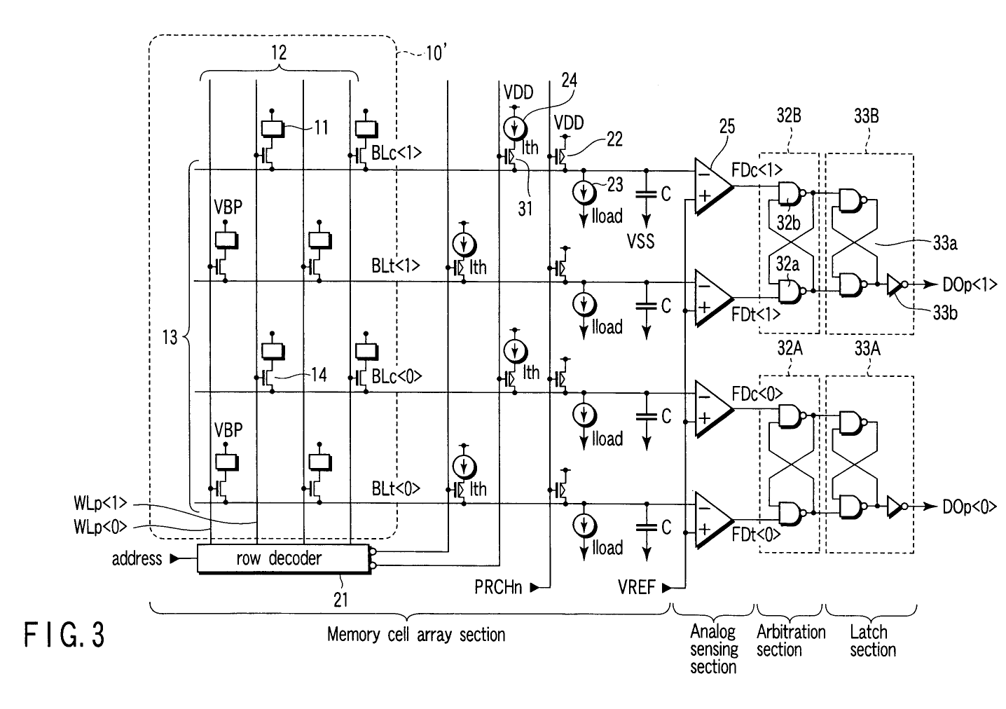

FIG. 3 shows a basic configuration of a semiconductor memory device according to a second embodiment of the present invention. The second embodiment will be described taking an embedded nonvolatile memory having a self-timing control sense amplifier as an example. The same components as those of the nonvolatile memory according to the first embodiment are denoted by the same reference numerals and their detailed descriptions are omitted.

As shown in FIG. 3, the bit lines are paired to keep a balance between their potentials, and one of the paired bit lines is employed as a reference bit line to improve data read accuracy. In this respect, the embedded nonvolatile memory of the second embodiment widely differs from that of the first embodiment. More specifically, a memory cell array 10′ includes a plurality of antifuse elements (nonvolatile storage elements) 11 which are arranged in matrix and each formed of a normal MOS transistor element. The antifuse elements 11 hold data by irreversibly varying electrical characteristics such as the variations of resistance, capacity, voltage and current. In the memory cell array 10′, a plurality of row selection lines (WL) 12 (four row selection lines are shown in FIG. 3) are arranged in the row direction, and a plurality of pairs of bit lines 13 are arranged in the column direction (two pairs of bit lines are shown in FIG. 3, and one of the pairs includes a true bit line BLt<0> a complementary bit line BLc<0> the other includes a true bit line BLt<1> a complementary bit line BLc<1>).

In the second embodiment, the antifuse elements 11 are alternated at the nodes of the row selection lines 12 and bit lines 13. More specifically, the antifuse elements 11 are connected to the nodes of odd-numbered row selection lines 12 and true bit lines BLt<0> BLt<1> 13 and the nodes of even-numbered row selection lines 12 and complementary bit lines BLc<0> BLc<1>13 via selection switches 14. One terminal (e.g., gate electrode) of an antifuse element 11 is connected to its corresponding selection switch 14. The other terminals (e.g., source, drain and well or substrate) thereof are connected to a high-voltage source. A high voltage VBP at which the gate insulation film of the antifuse element 11 can be broken is applied in programming (selection) mode.

The gate electrode of each of the selection switches 14 is connected to its corresponding row selection line 12. The row selection line 12 is activated by a row decoder 21 selectively in response to an address signal supplied from outside the memory.

A precharge unit 22 and a charge extraction unit 23 are connected to each of the bit lines 13. The precharge unit 22 precharges each of the bit lines 13 with a voltage (e.g., power supply voltage VDD). The charge extraction unit 23 extracts charges from each of the bit lines 13 in accordance with the same current characteristic (Iload). The precharge unit 22 is configured by, e.g., a P-type MOS transistor connected between the power supply voltage VDD and each of the bit lines 13, and activated by a precharge signal (PRCHn) which is to be supplied to each of the gate electrodes from outside the memory.

A recharge unit 24 is also connected to each of the bit lines 13 via a recharge switch 31 that is formed of a P-type MOS transistor. The recharge unit 24 recharges each of the bit lines 13 with current (Ith) whose amount is smaller than that of current (I) extracted by the charge extraction unit 23. The recharge unit 24 is activated by controlling the gate electrode of the recharge switch 31 through an address signal line in response to a control signal corresponding to each of even-numbered or odd-numbered address signals from the row recorder 21.

A memory cell array section of the nonvolatile memory according to the second embodiment, which has the configuration described above, is achieved.

The nonvolatile memory according to the second embodiment also includes an analog sensing section. In other words, a differential amplifier 25 is connected to each of the bit lines 13 to compare a bit line potential with a reference potential (VREF) applied from outside the memory.

Further, the nonvolatile memory according to the second embodiment includes an arbitration section (first set/reset (SR) latch). The arbitration section has arbiters 32A and 32B. The arbiter 32A is configured by cross-connecting two NAND gates 32a and 32b that receive outputs FDt<0> and FDc<0> from differential amplifiers 25, and the arbiter 32B is configured by cross-connecting two NAND gates 32a and 32b that receive outputs FDt<1> and FDc<1> from differential amplifiers 25. The arbiters 32A and 32B compare the outputs FDt<0> and FDc<0> the outputs FDt<1> and FDc<1> determine which of the outputs is set at high potential first.

In the nonvolatile memory, a latch unit (second SR latch) is provided at the output stage of the arbitration section. The latch unit amplifies the outputs of the arbiters 32A and 32B by output buffers 33A and 33B which are formed of an SR latch 33a and an inverter 33b. The amplification results of the output buffers 33A and 33B become read signals (output current or electrical signal) DOp<0> and DOp<1> of the read signals.

A procedure for reading data from the antifuse elements 11 in the nonvolatile memory described above (read operation) will be described.

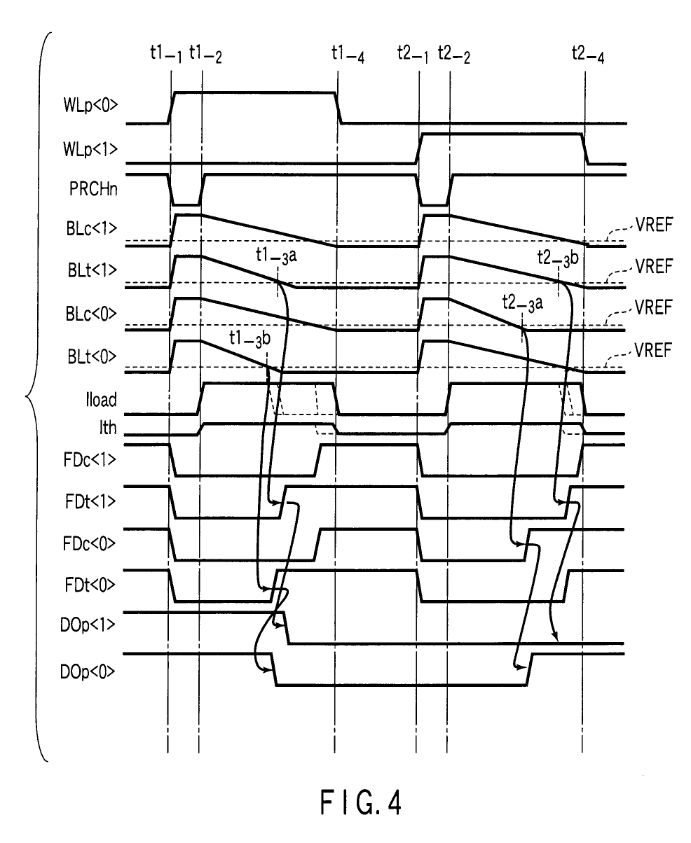

FIG. 4 is a timing chart, and its horizontal axis indicates a lapse of time. The timing chart shows variations (behavior) of potential and current of signals. The timing chart also shows two read operations. In FIG. 4, t1-₁, t1-₂, t1-₃ and t1-₄ represent first read operations and t2-₁, t2-₂, t2-₃, t2-₄ represent second read operations. The timing chart is prepared for illustrating a flow of the read operation in the second embodiment, and the values of time, potential, current or the like are not correct. For easy understanding, the number of row selection lines 12 is set to two (e.g., WLp<0>, WLp<1>).

First, data is read out of an antifuse element 11 as a first read operation. Assume here that one of the two row selection lines 12 (e.g., WLp<0>) is selected in response to an address signal supplied to a row decoder 21 (the other row selection line 12, e.g., WLp<1> is not selected). At the same timing t1-₁, a precharge signal PRCHn is supplied at the same timing t1-₁. The precharge signal PRCHn is a signal of negative logic and its low-potential state is an active one. Then, the precharge unit 22 using the precharge signal PRCHn as a gate signal is brought into conduction, and the potentials of all of the bit lines 13 become high.

At timing t1-₂, the precharge signal PRCHn is returned to an inactive state with the row selection line (WLp<0>) 12 kept in the selected state. At the same timing, the charge extraction unit 23 and recharge unit 24 are activated. Accordingly, the current characteristic Iload and current amount Ith increase.

When an odd-numbered row selection line (e.g., WLp<0>) 12 is selected, the recharge switch 31 corresponding to an even-numbered address signal supplied from the row decoder 21 is brought into conduction and thus only the recharge units connected to the complementary bit lines (BLc<0>, BLc<1>) 13 are activated. After that, the complementary bit lines operate as reference bit lines (RBL) in a pseudo manner.

In either case, charges are extracted from a capacitor C added to each of the bit lines (BLt<0>, BLc<0>, BLt<1>, BLc<1>) 13, and the potential of each of the bit lines lowers gradually, which is shown in the timing chart of FIG. 4 as a behavior of the potentials of the bit lines 13 at the timing after t1-₂.

When no data is written to a selected antifuse element 11, or when an antifuse element 11 is in a nonconducting state where it hardly causes cell current (Icell) to flow therethrough, the potentials of the true bit lines (BLt<0>, BLt<1>) 13 vary more sharply than those of complementary bit lines (BLc<0>, BLc<1>) 13 corresponding to the reference bit line (RBL). The reason for this is as follows. The charge extraction unit 23 extracts charges from the true bit lines (BLt<0>, BLt<1>) 13 for reading data in accordance with the current characteristic Iload, while the recharge unit 24 recharges the complementary bit lines (BLc<0>, BLc<1>) 13 in accordance with the current amount Ith at the same time when the unit 23 extracts charges from the complementary bit lines (BLc<0>, BLc<1>) 13 in accordance with the current characteristic Iload. If, therefore, the cell current Icell that flows through an antifuse element 11 for reading data does not exceed the current amount Ith of the recharge unit 24, the potentials of the true bit lines (BLt<0>, BLt<1>) 13 decrease more quickly than those of the complementary bit lines (BLc<0>, BLc<1>) 13.

However, the current amount Ith of the recharge unit 24 has to be smaller than the current characteristic Iload of the charge extraction unit 23. The speed at which the potential of each of the bit lines (BLt<0>, BLc<0>, BLt<1>, BLc<1>) 13 decreases depends upon the current characteristic Iload of the unit 23, the current amount Ith of the unit 24 and the capacitance C of each of the bit lines (BLt<0>, BLc<0>, BLt<1>, BLc<1>) 13. The parasitic capacitance of each of the bit lines (BLt<0>, BLc<0>, BLt<1>, BLc<1>) 13 can be used as the capacitance C, or a capacitive element having an adequate capacitance can be added in order to control the speed at which the potential of each of the bit lines 13 lowers.

Then, the potentials of the selected bit lines (BLt<0>, BLt<1>) 13 each become equal to the reference potential VREF indicated by the broken line at timing t1-₃ₐ and timing t1-_{3b}. This state (outputs FDt<0>, FDt<1>) is detected by the differential amplifier 25 that compares the potentials of the true bit lines (BLt<0>, BLt<1>) 13 and the reference potential VREF. In other words, only the outputs FDt<0> and FDt<1> of the differential amplifier 25 are increased in potential. Thus, the arbiters 32A and 32B detect that the potentials of outputs FDt<0> and FDt<1> of differential amplifier 25 become high earlier than those of outputs FDc<0> and FDc<1> thereof, and the states of the potentials are maintained. The outputs of the arbiters 32A and 32B are sent to the output buffers 33A and 33B and converted into read signals DOp<0> and DOp<1>, respectively. The states of the read signals DOp<0> and DOp<1> are maintained by the output buffers 33A and 33B until the next read operation is completed.

Finally, at timing t1-₄, the row selection line (WLp<0>) 12 is returned to an inactive state, and the charge extraction unit 23 and recharge unit 24 are each returned to an inactive state.

The above operation is a read operation for reading data from the antifuse element 11 in the first row from t1-₁ to t1-₄.

Then, a read operation for reading data from an antifuse element 11 in a second row is performed from t2-₁ to t2-₄. Since this read operation is almost the same as the above preceding read operation for reading data from the element 11 in the first row, only different operations will be described.

Of the row selection lines 12, a row selection line (WLp<1>) 12 in the second row is selected first at timing t2-₁. Then, at timing t2-₂, the precharge unit 22 is inactivated, while the charge extraction unit 23 and recharge unit 24 are activated, as in the preceding read operation.

In the read operation, when an antifuse element 11 connected to an even-numbered row selection line (WLp<1>) 12 is selected, only the recharge unit 24 connected to the true bit lines (BLt<0>, BLt<1>) 13 is activated. After that, the true bit lines (BLt<0>, BLt<1>) 13 operate as reference bit lines (RBL) in a pseudo manner.

In either case, charges are extracted from a capacitor C added to each of the bit lines (BLt<0>, BLc<0>, BLt<1>, BLc<1>) 13, and the potential of each of the bit lines lowers gradually, which is shown in the timing chart of FIG. 4 as a behavior of the potentials of the bit lines 13 at the timing after t2-2.

Let us consider that no data is written to those of the antifuse elements 11 selected in the read operation, which are connected to the bit line (BLc<0>) 13 and data is written to those of the antifuse elements 11, which are connected to the bit line (BLc<1>) 13.

First, the read operation of the bit line (BLc<0>) 13 to which an antifuse element 11 in which no data is stored, or an antifuse element 11 through which almost no cell current flows, operates as if the true and complementary bit lines BLt<0> and BLc<0> were replaced with each other. In other words, the charge extraction unit 23 extracts charges from the complementary bit line (BLc<0>) 13 for reading data in accordance with the current characteristic Iload. In contrast, the unit 23 extracts charges from the true bit line (BLt<0>) 13 in accordance with the current characteristic Iload and at the same time the recharge unit 24 recharges the true bit line (BLt<0>) 13 in accordance with the current amount Ith.

At t2-3a, the potential of the bit line (BLc<0>) 13 for reading data first becomes equal to the reference potential VREF indicated by the broken line. This state is detected by the differential amplifier 25 that compares the potential of the complementary bit line (BLc<0>) 13 and the reference potential VREF. Then, the potential of output FDc<0> of the differential amplifier 25 becomes high. Thus, the arbiter 32A detects that the potential of the output FDc<0> of the differential amplifier 25 becomes high earlier than that of output FDt<0> thereof, and the state of the potential is maintained. The output of the arbiter 32A is sent to the output buffer 33A and converted into a read signal DOp<0>.

The read operation of a bit line (BLc<1>) 13 to which an antifuse element 11 that stores data, or an antifuse element 11 through which cell current Icell flows more than threshold current (Ith) is connected, is performed as follows. In other words, the charge extraction unit 23 extracts charges from the complementary bit line (BLc<0>) 13 for reading data in accordance with the current characteristic Iload. In contrast, the unit 23 extracts charges from the true bit line (BLt<0>) 13 in accordance with the current characteristic Iload and at the same time the recharge unit 24 recharges the true bit line (BLt<0>) 13 in accordance with the current amount Ith.

The complementary bit line (BLc<0>) 13 for reading data is recharged by the antifuse element 11 electrically connected thereto in accordance with the cell current Icell. When the cell current Icell is larger than the threshold current Ith, the potential of the true bit line (BLt<1>) 13 decrease more quickly than that of the complementary bit line (BLc<1>) 13.

However, the variations of electrical characteristics due to the presence or absence of stored data are often very small in the antifuse element 11, as has been pointed out as the problem of prior art. When the cell current Icell is not so larger than the threshold value Ith, there is no great difference in behavior between the potential of the complementary bit line (BLc<1>) 13 for reading data and that of the true bit line (BLt<1>) 13 serving as a reference bit line. If the cell current Icell is slightly larger than the threshold value Ith, the potential of the true bit line (BLt<1>) 13 becomes equal to the reference potential VREF indicated by the broken line earlier than the potential of the complementary bit line (BLc<1>) 13 at t2-₃b. This state is detected by a differential amplifier 25 that compares the potential of the complementary bit line (BLc<1>) 13 and the reference potential VREF and a differential amplifier 25 that compares the potential of the true bit line (BLt<1>) 13 and the reference potential VREF. The outputs FDt<1> and FDc<1> of these differential amplifiers 25 are each set at high potential.

A slight time difference is detected by the arbiter 32B and its state is held. The output of the arbiter 32B is sent to the output buffer 33B and converted into a read signal DOp<1>.

The selected antifuse element 11 is connected to the complementary bit line (BLc<1>) 13. If, therefore, the antifuse element 11 does not store data, its read signal DOp<1> is set at high potential. Conversely, if the antifuse element 11 stores data, its read signal DOp<1> is set at low potential. Under this condition, the antifuse element 11 can be used. If, however, it is unfavorable that the stored data is inverted by an address signal, a logical circuit has only to be added in order to invert the read signals DOp<0> and DOp<1> and output the inverted signals when an even-numbered row selection line (even-numbered address) 12 is accessed.

Finally, at t2-₄, the row selection line (WLp<1) 12 is returned to an inactive state, as is the charge extraction unit 23 and recharge unit 24.

The above operation is a read operation for reading data from the antifuse element 11 in the second row from t2-₁ to t2-₄.

In the second embodiment, too, when the variations of electrical characteristics due to the presence or absence of data stored in an antifuse element are very small, the stored data can be read out with high precision and at high speed. In the embedded nonvolatile memory of the second embodiment, one of the paired bit lines is used as a reference bit line. Even though the changes of electrical characterritics of an antifuse element are very small, data can be read out of the antifuse element at high speed without using a high-precision analog amplifier or causing a large current to flow through the antifuse element.

According to the second embodiment, external timing control is unnecessary, and an output signal can easily be determined by prescribing an amount of current.

The above first and second embodiments are described taking an antifuse element as an example of a nonvolatile storage element. The present invention is not limited to the antifuse element, but can be applied to, for example, a current fuse element and a laser fuse element.

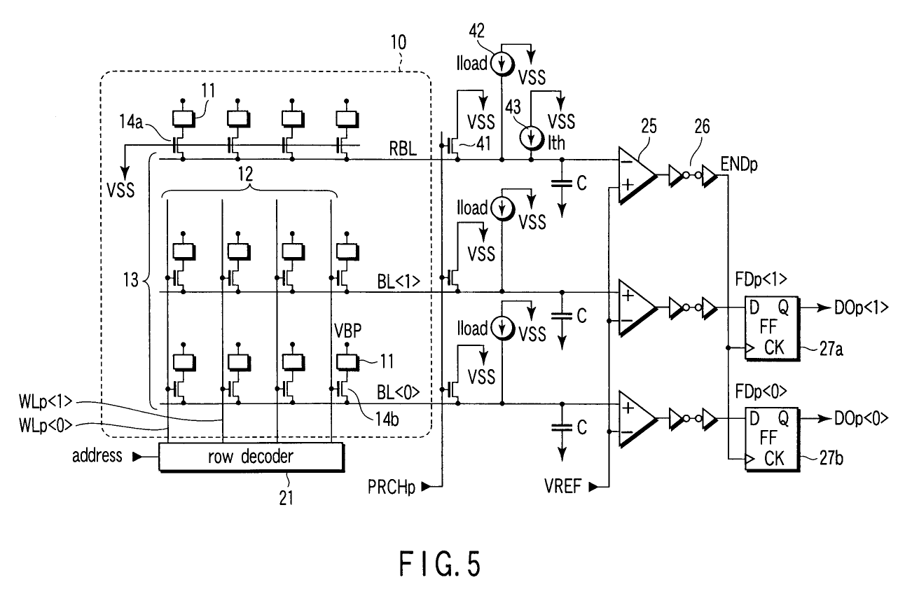

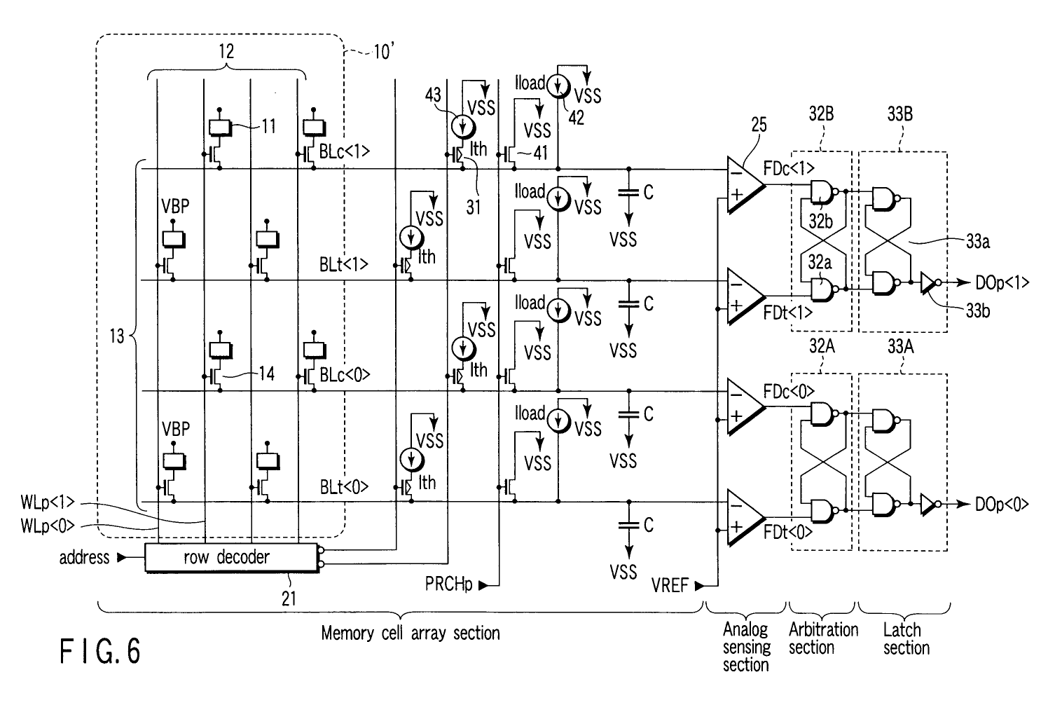

In each of the first and second embodiments, a bit line is precharged with power supply voltage VDD and its potential is extracted by the charge extraction unit. The present invention is not limited to this. As shown in FIGS. 5 and 6, a bit line can be precharged with ground potential (VSS) by a precharge unit 41 and it can be charged by a fuse element 11. In other words, a charge extraction unit 42 for extracting charges by current characteristics Iload having the same negative-value is connected to a selection bit line and a reference bit line, and a recharge unit 43 for recharging the reference bit line with a negative current amount Ith which is smaller than the negative current characteristic Iload can be connected thereto.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a plurality of row selection lines arranged in a row direction;
a plurality of bit lines arranged in a column direction;
a plurality of nonvolatile storage elements arranged at nodes between the row selection lines and the bit lines, the nonvolatile storage elements storing data by irreversibly varying electrical characteristics;
at least one reference bit line arranged in the column direction;
a precharge unit to precharge the reference bit line and a selection bit line of the bit lines with a same potential, the selection bit line being connected to a target nonvolatile storage element from which data is to be read;
a charge extraction unit to extract charges from the reference bit line and the selection bit line with a same current characteristic;
a recharge unit which is connected to the reference bit line to recharge the reference bit line with a current that is smaller than the charges extracted by the charge extraction unit;
a plurality of differential amplifiers which compare a potential of the reference bit line and a potential of the selection bit line with a reference potential; and
an output circuit which outputs data from the target nonvolatile storage element connected to the selection bit line, based on outputs of the differential amplifiers.

2. The semiconductor memory device according to claim 1, wherein a given number of nonvolatile storage elements arranged in the column direction are connected to the bit lines via selection switches selected by the row selection lines.

3. The semiconductor memory device according to claim 1, wherein a given number of nonvolatile storage elements arranged in the column direction are connected to the reference bit line via selection switches that are not brought into conduction.

4. The semiconductor memory device according to claim 3, wherein the given number of nonvolatile storage elements are dummy storage elements not used as storage elements to store data.

5. The semiconductor memory device according to claim 1, wherein the output circuit includes a plurality of flip-flops, and latches an output of a differential amplifier connected to the selection bit line the instant the potential of the reference bit line becomes equal to the reference potential when the precharge unit is inactivated and the charge extraction unit and the recharge unit are activated after a row selection line to which the target nonvolatile storage element is connected is held in a selective state at the same time when the precharge unit is activated to precharge the reference bit line and the selection bit line.

6. The semiconductor memory device according to claim 5, wherein the precharge unit precharges the reference bit line and the selection bit line with a power supply voltage, the charge extraction unit extracts charges from the reference bit line and the selection bit line in accordance with a positive current characteristic, and the recharge unit recharges the reference bit line in accordance with a positive current.

7. The semiconductor memory device according to claim 5, wherein the precharge unit precharges the reference bit line and the selection bit line with a ground potential, the charge extraction unit extracts charges from the reference bit line and the selection bit line in accordance with a negative current characteristic, and the recharge unit recharges the reference bit line in accordance with a negative current.

8. The semiconductor memory device according to claim 1, wherein the reference bit line and the selection bit line each include a capacitive element.

9. A semiconductor memory device comprising:
a plurality of row selection lines arranged in a row direction;
a plurality of nonvolatile storage elements connected to the row selection lines via selection switches, the nonvolatile storage elements storing data by irreversibly varying electrical characteristics;
a plurality of bit lines arranged in a column direction, the bit lines being a pair of bit lines including a true bit line and a complementary bit line, a given number of nonvolatile storage elements arranged in the column direction being connected to one of the true and complementary bit lines via selection switches selected by odd-numbered row selection lines of the row selection lines, a given number of nonvolatile storage elements arranged in the column direction being connected to the other of the true and complementary bit lines via selection switches selected by even-numbered row selection lines of the row selection lines, and the one of the true and complementary bit lines being set as a selection bit line and the other of the true and complementary bit lines being set as a reference bit line in accordance with a target storage element from which data is to be read;
a precharge unit to precharge the reference bit line and the selection bit line with a same potential;
a charge extraction unit to extract charges from the reference bit line and the selection bit line with a same current characteristic;
a recharge unit which recharges the reference bit line with a current that is smaller than the charges extracted by the charge extraction unit;
a plurality of differential amplifiers which compare a potential of the reference bit line and a potential of the selection bit line with a reference potential; and
an output circuit which outputs data from the target nonvolatile storage element connected to the selection bit line, based on outputs of the differential amplifiers.

10. The semiconductor memory device according to claim 9, wherein the output circuit includes a detection circuit that detects which of outputs of a differential amplifier connected to the reference bit line and a differential amplifier connected to the selection bit line is first set at a potential that is lower than the reference potential when the precharge unit is inactivated and the charge extraction unit and the recharge unit are activated, while a row selection line to which the target nonvolatile storage element is connected is held in a selective state, after the precharge unit is activated to precharge the reference bit line and the selection bit line.

11. The semiconductor memory device according to claim 10, wherein the precharge unit precharges the reference bit line and the selection bit line with a power supply voltage, the charge extraction unit extracts charges from the reference bit line and the selection bit line in accordance with a positive current characteristic, and the recharge unit recharges the reference bit line in accordance with a positive current.

12. The semiconductor memory device according to claim 10, wherein the precharge unit precharges the reference bit line and the selection bit line with a ground potential, the charge extraction unit extracts charges from the reference bit line and the selection bit line in accordance with a negative current characteristic, and the recharge unit recharges the reference bit line in accordance with a negative current.

13. The semiconductor memory device according to claim 9, wherein the reference bit line and the selection bit line each include a capacitive element.

14. A semiconductor memory device comprising:
a plurality of row selection lines arranged in a row direction;
a plurality of nonvolatile storage elements connected to the row selection lines via selection switches, the nonvolatile storage elements storing data by irreversibly varying electrical characteristics;
a plurality of bit lines arranged in a column direction, the bit lines being a pair of bit lines including a true bit line and a complementary bit line, a given number of nonvolatile storage elements arranged in the column direction being connected to one of the true and complementary bit lines via selection switches selected by odd-numbered row selection lines of the row selection lines, a given number of nonvolatile storage elements arranged in the column direction being connected to the other of the true and complementary bit lines via selection switches selected by even-numbered row selection lines of the row selection lines, and the one of the true and complementary bit lines being set as a reference bit line and the other of the true and complementary bit lines being set as a selection bit line in accordance with a target storage element from which data is to be read;
a precharge unit to precharge the reference bit line and the selection bit line with a same potential;
a charge extraction unit to extract charges from the reference bit line and the selection bit line with a same current characteristic;
a recharge unit which recharges the reference bit line with a current that is smaller than the charges extracted by the charge extraction unit;
a plurality of differential amplifiers which compare a potential of the reference bit line and a potential of the selection bit line with a reference potential; and
an output circuit which outputs data from the target nonvolatile storage element connected to the selection bit line, based on outputs of the differential amplifiers.

15. The semiconductor memory device according to claim 14, wherein the output circuit includes a detection circuit that detects which of outputs of a differential amplifier connected to the reference bit line and a differential amplifier connected to the selection bit line is first set at a potential that is lower than the reference potential when the precharge unit is inactivated and the charge extraction unit and the recharge unit are activated, while a row selection line to which the target nonvolatile storage element is connected is held in a selective state, after the precharge unit is activated to precharge the reference bit line and the selection bit line.

16. The semiconductor memory device according to claim 15, wherein the precharge unit precharges the reference bit line and the selection bit line with a power supply voltage, the charge extraction unit extracts charges from the reference bit line and the selection bit line in accordance with a positive current characteristic, and the recharge unit recharges the reference bit line in accordance with a positive current.

17. The semiconductor memory device according to claim 15, wherein the precharge unit precharges the reference bit line and the selection bit line with a ground potential, the charge extraction unit extracts charges from the reference bit line and the selection bit line in accordance with a negative current characteristic, and the recharge unit recharges the reference bit line in accordance with a negative current.

18. The semiconductor memory device according to claim 14, wherein the reference bit line and the selection bit line each include a capacitive element.
